(19) United States
(12) Patent Application Publication
(10) Pub. No.: US 2013/0075764 A1
(43) Pub. Date: Mar. 28, 2013

(54) OPTICAL MODULE PACKAGE STRUCTURE

(71) Applicant: Chao-Wei YU, Taichung City (TW)

(72) Inventor: Chao-Wei YU, Taichung City (TW)

(21) Appl. No.: 13/288,747

(22) Filed: Nov. 3, 2011

(30) Foreign Application Priority Data
Sep. 27, 2011 (TW) 100218094

(51) Int. Cl. H01L 31/12

(52) U.S. Cl. 257/82; 257/E33.058; 257/E33.077

(57) ABSTRACT

An optical module package structure includes a light-emitting chip and a light sensor chip respectively installed in a first cavity and a second cavity in a substrate, a reflective layer coated on the periphery of the first cavity, two packaging adhesive structures respectively molded in the first cavity and the second cavity to encapsulate the light-emitting chip and the light sensor chip respectively, and a lid integrally formed on the substrate to enhance the airtightness of the whole optical module package structure.

### BACKGROUND OF THE INVENTION

1. Field of the Invention

The present invention relates to optical module packaging technology and more particularly, to an optical module package structure, which effectively lowers the optical module packaging cost and improves its light sensing efficiency.

2. Description of the Related Art

To avoid accidental touching of the touch screen or to save power consumption, a handheld electronic device (such as smart phone) is generally equipped with a proximity optical sensor module. When the handheld electronic device is in proximity to the surface of an object (for example, the face of a person), the proximity optical sensor module is induced to switch off a part of the power supply. The proximity optical sensor module uses a light-emitting chip to emit a light source, and a light sensor chip to receive the light that is emitted by the light-emitting chip and reflected by a media (for example, the face) and then to convert the light signal into an electronic signal for further processing.

The aforesaid conventional proximity optical sensor module is made by separately packaging the light-emitting chip and the light sensor chip into a respective individual package and then mounting the two individual packages together to form a module. As the light-emitting chip and the light sensor chip are separately packaged, the packaging cost of the proximity optical sensor module remains high. Further, when the light beam emitted by the light-emitting chip falls upon a rough surface of an object, the light sensor chip may be unable to positively sense the reflected light beam from the object, affecting further reading result.

### SUMMARY OF THE INVENTION

The present invention has been accomplished under the circumstances in view. It is the main object of the present invention to provide an optical module package structure, which effectively lowers the manufacturing cost and improves the light sensing efficiency.

To achieve these and other objects of the present invention, an optical module package structure comprises a substrate, a light-emitting chip, a light sensor chip, a lid and two packaging adhesive members. The substrate defines a light-emitting zone, a light-sensing zone, a first cavity in the light-emitting zone and a second cavity in the light-sensing zone. The first cavity is covered with a reflective layer. The light-emitting chip is mounted in the first cavity of the substrate and adapted for emitting light. The light sensor chip is mounted in the second cavity of the substrate and adapted for sensing a light beam. The two packaging adhesive structures are respectively molded in the first cavity and the second cavity to encapsulate the light-emitting chip and the light sensor chip for protection. The lid is integrally formed on the substrate, comprising a light-emitting hole and a light-sensing hole respectively aimed at the first cavity and second cavity of the substrate.

Thus, the optical module package structure of the present invention enables the light-emitting chip and the light sensor chip be directly installed in one same substrate and synchronously packaged, effectively lowering the manufacturing cost.

Subject to the design of the reflective layer, the invention greatly improves the light sensing efficiency of the optical module package structure.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is a schematic top view of an optical module package structure in accordance with the present invention.

FIG. 2 is a sectional view taken along line 2-2 of FIG. 1.

### DETAILED DESCRIPTION OF THE INVENTION

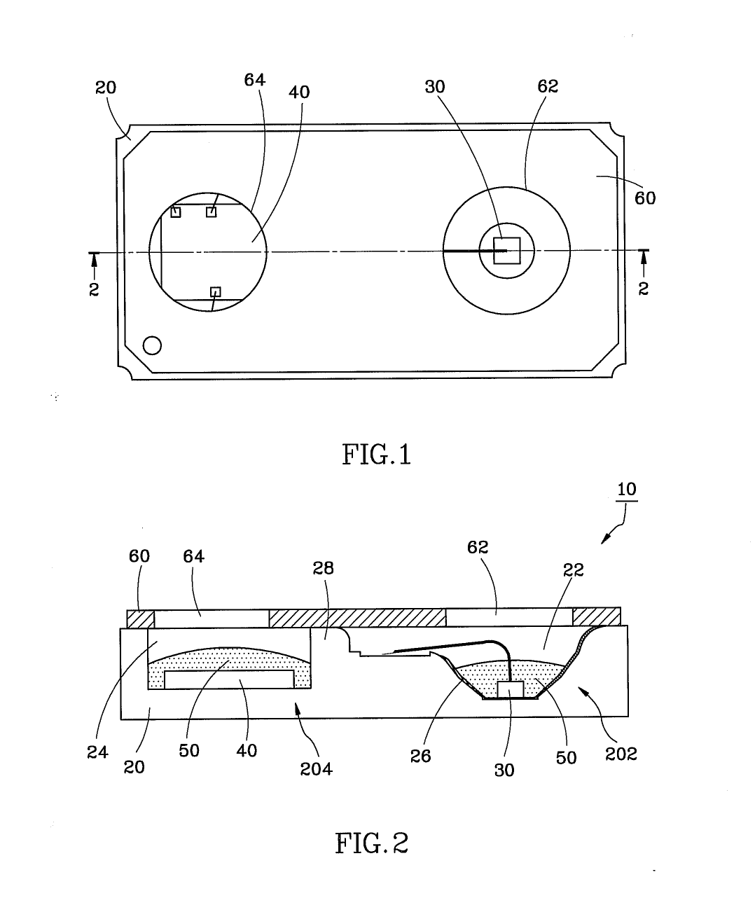

Referring to FIGS. 1 and 2, an optical package structure 10 in accordance with the present invention is shown comprising a substrate 20, a light-emitting chip 30, a light sensor chip 40, two packaging adhesive members 50 and a lid 60.

The substrate 20 according to this embodiment is a ceramic substrate, defining a light-emitting zone 202, a light-sensing zone 204, a first cavity 22 in the light-emitting zone 202, a second cavity 24 in the light-sensing zone 204, and a partition portion 28 in between the light-emitting zone 202 and the light-sensing zone 204 to keep the light-emitting zone 202 and the light-sensing zone 204 apart. The first cavity 22 expands gradually upwards. The second cavity 24 extends upwardly in an equal diameter manner. Further, the first cavity 22 is covered with a reflective layer 26 of metal substance by means of a coating technique.

The light-emitting chip 30 is mounted in the first cavity 22 of the substrate 20 and adapted for emitting light.

The light sensor chip 40 is mounted in the second cavity 24 of the substrate 20 and adapted for sensing a light beam.

The packaging adhesive structures 50 are prepared from, for example, transparent epoxy resin and respectively molded in the first cavity 22 and the second cavity 24 to encapsulate the light-emitting chip 30 and the light sensor chip 40 for protection.

The lid 60 is integrally formed on the substrate 20 to enhance the airtightness of the optical package structure 10, comprising a light-emitting hole 62 and a light-sensing hole 64 respectively aimed at the first cavity 22 and second cavity 24 of the substrate 20 for letting light passes.

Based on the aforesaid structural arrangement, light beam emitted by the light-emitting chip 30 goes through the light-emitting hole 62 of the lid 60 to fall upon the surface of an eternal object. The light beam reflected by the external object goes through the light-sensing hole 64 of the lid 60 to fall upon the light sensor chip 40, which converts the light signal into a corresponding electronic signal for recording and processing. Subject to the design of the reflective layer 26, the light beam emitted by the light-emitting chip 30 and then reflected by a rough surface the external object can be positively received by the light sensor chip 40 during the light emitting and sensing operation of the optical package structure 10, enhancing the light sensing effect. On the other hand, the light-emitting chip 30 and the light sensor chip 40, unlike the prior art independent packaging technique, are synchronously packaged on the same substrate 20, effectively lowering the manufacturing cost.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. An optical module package structure, comprising:
a substrate defining a light-emitting zone, a light-sensing zone, a first cavity in said light-emitting zone and a second cavity in said light-sensing zone, said first cavity being covered with a reflective layer;
a light-emitting chip mounted in said first cavity of said substrate and adapted for emitting light;
a light sensor chip mounted in said second cavity of said substrate and adapted for sensing a light beam;
two packaging adhesive structures respectively molded in said first cavity and said second cavity to encapsulate said light-emitting chip and said light sensor chip for protection; and
a lid integrally formed on said substrate, said lid comprising a light-emitting hole and a light-sensing hole respectively aimed at said first cavity and said second cavity of said substrate.

2. The optical module package structure as claimed in claim 1, wherein said first cavity expands gradually upwards.

3. The optical module package structure as claimed in claim 1, wherein said second cavity extends upwardly in an equal diameter manner.

4. The optical module package structure as claimed in claim 1, wherein said substrate further comprises a partition portion disposed in between said light-emitting zone and said light-sensing zone to keep said light-emitting zone and said light-sensing zone apart.

5. The optical module package structure as claimed in claim 1, wherein said reflective layer is prepared by a metal substance.
